(19) United States
(12) Patent Application Publication
(10) Pub. No.: US 2020/0199737 A1
(43) Pub. Date: Jun. 25, 2020

(54) VACUUM EVAPORATION SOURCE

(71) Applicant: Alpha Plus Co., Ltd., Asan-si Chungcheongnam-do (KR)

(72) Inventor: Do Weon Hwang, Asan-si Chungcheongnam-do (KR)

(21) Appl. No.: 16/644,223

(22) PCT Filed: Sep. 14, 2017
(86) PCT No.: PCT/KR2017/010095

§ 371 Date: Mar. 4, 2020

(51) Int. Cl. C23C 14/24

(52) U.S. Cl. CPC C23C 14/24

(57) ABSTRACT

A vacuum evaporation source capable of improving the straightness of a heating wire. To this end, aspects of the present invention provide a vacuum evaporation source including a crucible, including a first heating wire for heating the crucible, and a first upper fixing portion for fixing an upper portion of the first heating wire.

### CROSS REFERENCE TO RELATED APPLICATION

This application is the U.S. National Phase Application of PCT/KR2017/010095, filed Sep. 14, 2017, the contents of such application being incorporated by reference herein.

### TECHNICAL FIELD

The present invention relates to a vacuum evaporation source used to form a thin film on a wafer or substrate.

### BACKGROUND ART

Generally, a vacuum evaporation source heats and evaporates materials for forming a thin film to form a predetermined thin film on a substrate disposed in a high vacuum chamber. It is used to form a thin film made of a specific material on a wafer surface in a semiconductor manufacturing process or to form a thin film of a desired material on a surface of a glass substrate or the like in a manufacturing process of a large flat panel display device.

FIG. 1 is a view schematically showing a conventional vacuum evaporation source.

As shown in FIG. 1, the conventional vacuum evaporation source includes a case 10 supported by a support rod 12 or the like and having an inner space 11, a crucible 20 provided in the inner space 11 and containing a material for forming a thin film, a heater 30 positioned between a side of the inner space 11 and an outer side of the crucible 20 to heat a side of the crucible 20, a side reflecting plate 40 provided between the side of the inner space 11 and the heater 30 to reflect the heat of the heater 30 to the side of the crucible 20, and a bottom reflecting plate 60 positioned at a bottom of the inner space 11 so that the heat of the heater 30 is relatively less transferred to a lower electric component 50 (which includes a power supply or temperature sensor) placed under the case 10. In particular, as shown in FIG. 1, the bottom reflecting plate 60 is positioned at the bottom of the inner space 11, and a lower end of the heater 30 is placed at a height substantially coincident with a lower end of the crucible 20.

In the conventional vacuum evaporation source, the bottom reflecting plate 60 is positioned at the bottom of the inner space 11 away from the crucible 20 and the heater 30 is not placed under the crucible 20, and thus there is a problem that the heat of the heater 30 is relatively less transferred to a bottom of the crucible 20.

### DISCLOSURE OF INVENTION

### Technical Problem

An aspect of the present invention is a vacuum evaporation source capable of heating a bottom of a crucible efficiently.

### Solution of Problem

Aspects of the present invention provide a vacuum evaporation source with a crucible in an inner space of a case, including: a bottom reflector positioned in an upper half of a lower space formed between a bottom of the crucible and a bottom surface of the inner space; a supporter provided on the bottom surface of the inner space to support the bottom reflector; and a heater positioned between a side of the inner space and an outer side of the crucible and extending to an upper surface of the bottom reflector.

The bottom reflector may have a module shape in which a plurality of reflecting plates are overlapped.

An uppermost reflecting plate positioned at the highest position of the plurality of reflecting plates may be made of an insulating material, and a lower end of the heater may be supported on an upper surface of the uppermost reflecting plate.

The uppermost reflecting plate may be made of ceramic as the insulating material, and may have a disk type.

The supporter may include a vertical support that is vertically placed on the bottom surface of the inner space; and a horizontal support provided at an upper end of the vertical support, provided to be horizontal to the bottom surface of the inner space, and on which the bottom reflector is seated, in which a height of the vertical support may be determined such that the bottom reflector is placed on the upper half of the lower space.

The vacuum evaporation source according to an embodiment of the present invention described above may further include a bottom reflecting plate provided on the bottom surface of the inner space.

### Advantageous Effects of Invention

As described above, the vacuum evaporation source according to the embodiment of the present invention may have the following effects.

According to the embodiment of the present invention, a technical configuration is provided that includes a bottom reflector, a supporter, and a heater. Therefore, the bottom reflector may be placed close to a bottom of the crucible and a lower end of the heater may extend to an upper surface of the bottom reflector, thereby efficiently heating the bottom of the crucible.

### BRIEF DESCRIPTION OF THE DRAWINGS

FIG. 1 is a view schematically showing a conventional vacuum evaporation source;

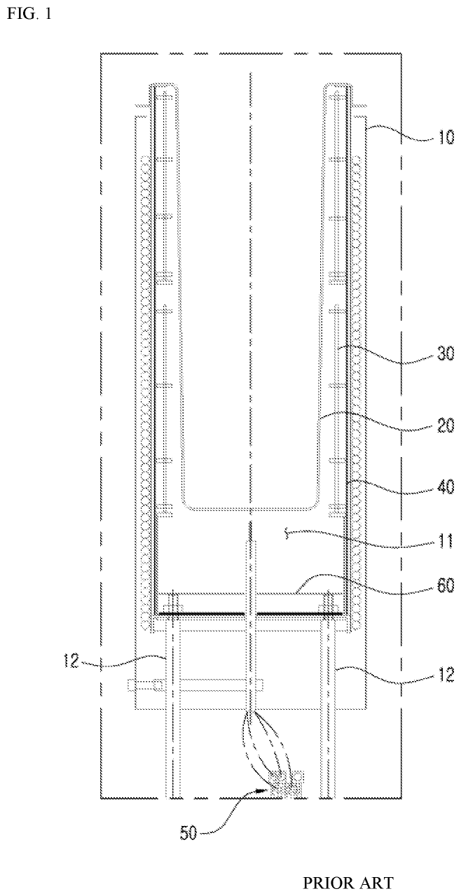

FIG. 2 is a view schematically showing a vacuum evaporation source according to an embodiment of the present invention; and

FIG. 3 is an enlarged view showing main parts of FIG. 2.

### MODE FOR THE INVENTION

Hereinafter, embodiments of the present invention will be described in detail with reference to the accompanying drawings so that those skilled in the art may easily implement aspects of the present invention. However, aspects of the invention may be implemented in many different forms, and it is not limited to embodiments described herein.

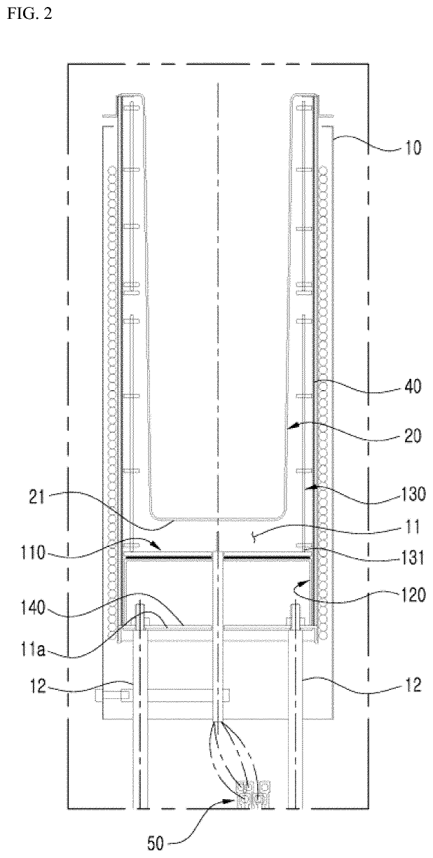

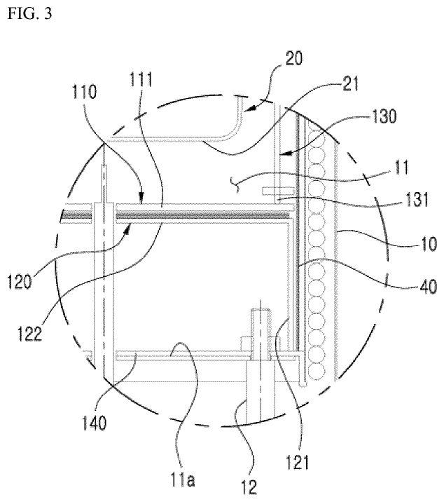

FIG. 2 is a view schematically showing a vacuum evaporation source according to an embodiment of the present invention, and FIG. 3 is an enlarged view showing main parts of FIG. 2.

As shown in FIGS. 2 and 3, a vacuum evaporation source with a crucible 20 in an inner space 11 of a case 10 according to an embodiment of the present invention includes a bottom reflector 110, a supporter 120, and a heater 130. Hereinafter, each component will be described in detail with continued reference to FIGS. 2 and 3.

The bottom reflector 110 is a component that reflects the heat of the heater 130 to the bottom of the crucible 20, and is positioned in the upper half of the lower space between the bottom 21 of the crucible 20 and the bottom surface 11a of the inner space 11 as shown in FIGS. 2 and 3. Therefore, the bottom reflector 110 may be placed close to the bottom 21 of the crucible 20, thereby efficiently heating the bottom 21 of the crucible 20.

For example, as shown in FIG. 3, the bottom reflector 110 may have a module shape in which a plurality of reflecting plates are overlapped. Therefore, even if the heat of the heater 130 is transferred over the uppermost reflecting plate 111 (the reflecting plate positioned at the highest of the plurality of reflecting plates), the reflection may be made in a manner reflected by the reflecting plate placed next, so that the reflection efficiency against heat may increase.

Furthermore, as shown in FIG. 3, the uppermost reflecting plate 111 positioned at the highest position of the plurality of reflecting plates may be made of an insulating material, and a lower end 131 of the heater 130 may be supported on an upper surface of the uppermost reflecting plate 111. Therefore, a portion of the heater 130 may be positioned at the upper half of the lower space described above (a space formed between the bottom 21 of the crucible 20 and the bottom surface 11a of the internal space 11), thereby sufficiently heating the bottom 21 of the crucible 20 through the heater 130 and the bottom reflector 110. In addition, since the uppermost reflecting plate 111 is made of an insulating material, the heater 130 may be prevented from shorting even when the heater 130 is in contact with the uppermost reflecting plate 111, thereby stably supporting the heater 130.

In particular, the uppermost reflecting plate 111 may be made of ceramic as an insulating material, and may have a disc type. Therefore, even when the heater 130 is thermally expanded or thermally contracted, it may be stably supported by the uppermost reflecting plate 111. In addition, the heat of the heater 130 may be more efficiently reflected to the bottom 21 of the crucible 20 by using a disc type ceramic.

The supporter 120 is a component supporting the bottom reflector 110 and is provided on the bottom surface 11a of the internal space 11 as shown in FIGS. 2 and 3.

For example, the supporter 120 may include a vertical support 121 and a horizontal support 122 as shown in FIG. 3. The vertical support 121 is placed perpendicular to the bottom surface 11a of the inner space 11. The horizontal support 122 is provided on an upper end of the vertical support 121 and is provided to be horizontal to the bottom surface 11a of the inner space 11, in which the bottom reflector 110 is seated thereon.

In particular, a height of the vertical support 121 may be determined such that the bottom reflector 110 is placed in the upper half of the lower space described above. Therefore, the bottom reflector 110 may be positioned close to the bottom 21 of the crucible 20 by the vertical support 121 so that the bottom 21 of the crucible 20 is efficiently heated.

The heater 130 is a component that heats the crucible 20 and the bottom reflector 110 described above. The heater 130 is positioned between the side of the inner space 11 and the outer side of the crucible 20, while its lower end 131 extends to the upper surface of the bottom reflector 110. Accordingly, the side and the bottom 21 of the crucible 20 may be directly heated by the heater 130, or the bottom 21 of the crucible 20 may be indirectly heated through the bottom reflector 110 described above. In addition, even when the heater 130 is thermally expanded or thermally contracted, the heater 130 may be stably supported by the uppermost reflecting plate 111 with the ceramic material described above.

In addition, as shown in FIGS. 2 and 3, the vacuum evaporation source according to the embodiment of the present invention described above may further include a bottom reflecting plate 140 provided on the bottom surface 11a of the internal space 11.

Therefore, since the heat of the heater 130 transferred over the bottom reflector 110 is reflected by the bottom reflecting plate 140 again, it is possible to minimize the heat transfer of the heater 130 to the electric component (see 50 of FIG. 2).

Furthermore, although not shown, in order to further minimize the heat of the heater 130 transferred to the electric component (see 50 of FIG. 2), the bottom reflecting plate 140 may have a module form formed of several layers.

As described above, the vacuum evaporation source according to the embodiment of the present invention may have the following effects.

According to the embodiment of the present invention, since it provides a technical configuration including the bottom reflector 110, the supporter 120, and the heater 130, the bottom reflector 110 may be placed close to the bottom 21 of the crucible 20 and the lower end 131 of the heater 130 may extend to the upper surface of the bottom reflector 110, thereby efficiently heating the bottom 21 of the crucible 20.

Although the preferred embodiment of the present invention has been described in detail above, the scope of aspects of the present invention are not limited thereto.

Various modifications and improvements of those skilled in the art using the basic concept of an aspect of the present invention as defined in the following claims are also within the scope of the present invention.

### INDUSTRIAL APPLICABILITY

Since the present invention relates to a vacuum evaporation source, it may be applied to manufacturing semiconductors or the like and thus has industrial applicability.

1. A vacuum evaporation source with a crucible in an inner space of a case, comprising:
a bottom reflector positioned in an upper half of a lower space formed between a bottom of the crucible and a bottom surface of the inner space;
a supporter provided on the bottom surface of the inner space to support the bottom reflector; and
a heater positioned between a side of the inner space and an outer side of the crucible and extending to an upper surface of the bottom reflector.

2. The vacuum evaporation source of claim 1, wherein the bottom reflector has a module shape in which a plurality of reflecting plates are overlapped.

3. The vacuum evaporation source of claim 2, wherein an uppermost reflecting plate positioned at the highest position of the plurality of reflecting plates is made of an insulating material, and
wherein a lower end of the heater is supported on an upper surface of the uppermost reflecting plate.

4. The vacuum evaporation source of claim 3, wherein the uppermost reflecting plate is made of ceramic as the insulating material, and has a disk type.

5. The vacuum evaporation source of claim 1, wherein the supporter comprises:
a vertical support that is vertically placed on the bottom surface of the inner space; and
a horizontal support provided at an upper end of the vertical support, provided to be horizontal to the bottom surface of the inner space, and on which the bottom reflector is seated,
wherein a height of the vertical support is determined such that the bottom reflector is placed on the upper half of the lower space.

6. The vacuum evaporation source of claim 1, further comprising:
a bottom reflecting plate provided on the bottom surface of the inner space.
